(19) United States
(12) Patent Application Publication
(10) Pub. No.: US 2020/0168534 A1
(43) Pub. Date: May 28, 2020

(54) MULTI-CHIP MODULE INCLUDING STANDALONE CAPACITORS

(71) Applicant: TEXAS INSTRUMENTS INCORPORATED, Dallas, TX (US)

(72) Inventors: Thomas Dyer BONIFIELD, Dallas, TX (US); Sreeram Subramanyam NASUM, Bangalore (IN); Robert H. EKLUND, Plano, TX (US); Jeffrey Alan WEST, Dallas, TX (US); Byron Lovell WILLIAMS, Plano, TX (US); Elizabeth Costner STEWART, Dallas, TX (US)

(21) Appl. No.: 16/202,663

(22) Filed: Nov. 28, 2018

(51) Int. Cl. H01L 23/495; H01L 21/48; H01L 23/00

(52) U.S. Cl. CPC H01L 23/49589; H01L 23/49503; H01L 23/4952; H01L 23/49575; H01L 2924/19041; H01L 24/48; H01L 2224/48245; H01L 2224/48465; H01L 21/4825

(57) ABSTRACT

In some examples, a multi-chip module (MCM), comprises a first and a second die-attach pad (DAP); a first die comprising a first set of microelectronic devices; a second die comprising a first capacitor and a second capacitor; and a third die comprising a second set of microelectronic devices, where the first and second dies are positioned on the first DAP, and the third die is positioned on the second DAP. The first set of microelectronic devices couples to the first capacitor via a first inter-die connection and the second set of microelectronic devices couples to the second capacitor via a second inter-die connection.

### BACKGROUND

Galvanic isolation capacitors are typically employed to electrically isolate microelectronic devices (e.g., transistors).

### SUMMARY

In accordance with some examples, a multi-chip module (MCM), comprises a first and a second die-attach pad (DAP); a first die comprising a first set of microelectronic devices; a second die comprising a first capacitor and a second capacitor; and a third die comprising a second set of microelectronic devices, where the first and second dies are positioned on the first DAP, and the third die is positioned on the second DAP. The first set of microelectronic devices couples to the first capacitor via a first inter-die connection and the second set of microelectronic devices couples to the second capacitor via a second inter-die connection.

In accordance with some examples, a multi-chip module (MCM), comprises a first die comprising a first integrated circuit (IC) coupled to a first inter-die connection; a second die comprising a first capacitor and a second capacitor; and a third die comprising a second IC coupled to a second inter-die connection. The first capacitor coupled to the first IC via the first inter-die connection and the second capacitor coupled to the second IC via the second inter-die connection.

In accordance with some examples, a method of packaging a multi-chip module (MCM), the method comprises placing a first die including a first integrated circuit (IC) on a first die-attach pad (DAP); placing a second die including a pair of asymmetrical capacitors on the first DAP; and placing a third die including a second IC on a second DAP.

### BRIEF DESCRIPTION OF THE DRAWINGS

For a detailed description of various examples, reference will now be made to the accompanying drawings in which:

FIG. 1 depicts an illustrative circuit, in accordance with various examples.

FIG. 2 depicts an illustrative cross-section side view of the circuit of FIG. 1, in accordance with various examples.

FIG. 3 depicts another illustrative cross-section side view of the circuit of FIG. 1, in accordance with various examples in accordance with various examples.

FIG. 4 depicts an illustrative method including the steps performed at a multi-chip module (MCM) packaging station, in accordance with various examples.

### DETAILED DESCRIPTION

A multi-chip package (MCP) or multi-chip module (MCM) refers to a packaging configuration containing multiple dies (e.g., two or more dies). Inter-die communication in the MCM is typically achieved by die-to-die wire bonding. In some cases, one of the inter-connected dies includes an isolation capacitor (e.g., galvanic isolation capacitor) that is configured to provide electrical isolation (e.g., high voltage isolation) between an input terminal positioned on one die and an output terminal positioned on the other die. For the sake of illustration, the description below describes an MCM that includes a collection of microelectronic devices (e.g., integrated circuit (IC)) forming a transmitter circuit fabricated on one die and another collection of microelectronic devices forming a receiver circuit fabricated on a different die. The isolation capacitor, in this disclosure, provides isolation between the transmitter circuit and the receiver circuit. In this disclosure, the transmitter and receiver circuits are also configured to send signals (or communicate) via the isolation capacitor. However, the description below is not limited to the dies including transmitter and receiver circuits and may apply to the dies including other ICs. For examples, digital/analog circuits requiring high voltage isolation, and capacitive sensing circuits.

In some cases, the electrical isolation between receiver and transmitter circuits is achieved by fabricating an isolation capacitor on the die with the receiver (and/or transmitter) circuit. In such cases, the voltage isolation and communication capabilities are limited by the isolation ability of the isolation capacitor. In some cases, a pair of series-connected isolation capacitors with substantially equal capacitance may be employed to increase the voltage isolation and communication capabilities (see, for example, patent U.S. Pat. No. 9,299,697B2). In such cases, one isolation capacitor is typically fabricated on the die with the transmitter circuit, and the other isolation capacitor is fabricated on the other die with the receiver circuit. In such cases, the lower plate of both the isolation capacitors is at a potential substantially similar to its respective substrate, and both the substrates typically operate at different voltage nodes. Further, the output terminal of the transmitter circuit couples to one isolation capacitor, which is series-connected to the other isolation capacitor that is further coupled to the receiver circuit.

The fabrication process of the isolation capacitor positioned on the same die as the IC may be similar. For example, a complementary metal oxide semiconductor (CMOS) process (or other suitable processes) may be used to fabricate both the IC and the isolation capacitor disposed on the same die. However, embedding the isolation capacitor on the die with the IC reduces the portability of the isolation capacitor since it has to be qualified with a technology node of the IC. The technology node refers to a semiconductor manufacturing process and its design rules. The time required to qualify the isolation capacitor for a given technology node can be extensive, as the test time for measuring time-dependent dielectric breakdown (TDDB) of the isolation capacitor to assess its expected lifetime can take several months. Once the isolation capacitor is qualified with a particular technology node, only then it can be built on that technology node. This lengthy qualification procedure must be repeated for every technology node incorporating an isolation capacitor.

Embedding the isolation capacitor also has higher fabrication costs and results in a larger die size as the embedded isolation capacitor is cost and size limited due to the design rules and cost associated with the underlying IC. Moreover, embedding isolation capacitors and ICs on the same die may require adding extra metal levels to achieve the isolation requirements of the capacitor, which are otherwise not required for fabricating the underlying ICs, which also adds to the overall cost. The above-described limitations can be circumvented by using a standalone isolation device that is fabricated on a separate die. The standalone galvanic isolation device, in some cases, includes transformers fabricated using multiple layers of polyimide and gold. However, such standalone isolation transformers have high fabrication costs, are large in area, and have lower isolation ratings than traditional silicon dioxide capacitors. Therefore, alternative systems are needed to mitigate the issues mentioned above.

Accordingly, at least some of the examples disclosed herein include an MCM comprising standalone isolation. The standalone isolation is fabricated on a separate substrate (e.g., silicon, or other suitable substrates). In at least some examples, the standalone isolation comprises a capacitor or multiple capacitors connected in series with the circuits disposed on other dies of the MCM. In at least some examples, the standalone capacitors employ one or more layers of thick (e.g., 10 micrometers or more) dielectrics positioned between a top metal layer and a bottom metal layer to form the standalone capacitors. In at least some examples, the MCM includes multiple die-attach pads (DAPs). In at least some examples, the die with the standalone capacitors is positioned on a separate die-attach pad (DAP). In some examples, the die with the standalone capacitors shares the DAP with another die including an IC.

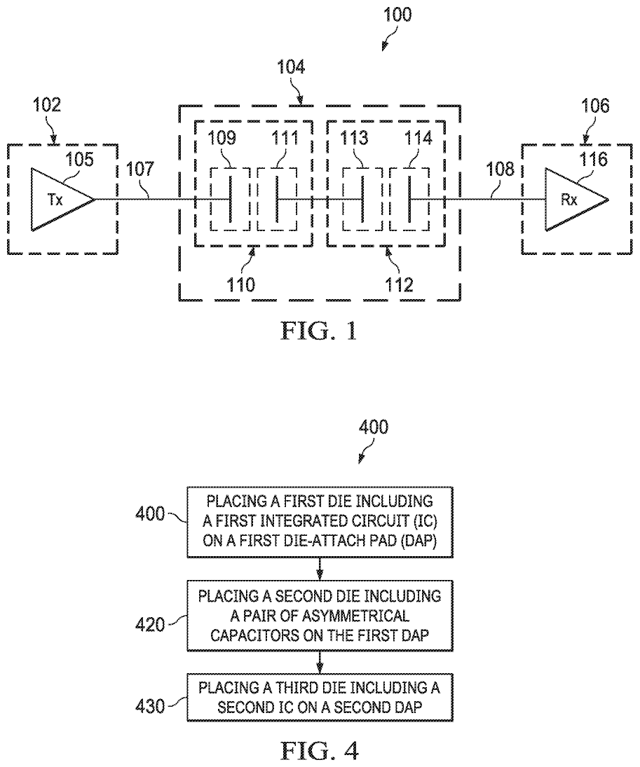

FIG. 1 depicts an illustrative circuit 100 that is positioned in an MCM (not expressly depicted). The circuit 100 includes a transmitter circuit 105 that is integrated on a semiconductor die 102. The transmitter circuit 105, in some examples, may include additional suitable circuitry (not expressly shown in FIG. 1), an oscillator circuit, modulator circuit, and amplifier circuit. The output of the transmitter circuit 105 transmits through an inter-die connection 107. The circuit 100 also includes a receiver circuit 116 that is integrated on a semiconductor die 106, where the receiver circuit 116 may include a filter, amplifier, demodulator, and related circuitry (not expressly shown in FIG. 1). The input of the receiver circuit 116 is received via an inter-die connection 108.

The circuit 100 further includes capacitors 110, 112, which are disposed in a die 104. The capacitor 110 has a first plate 109 and a second plate 111. For the sake of simplicity, the first plate 109 is referred to as top plate 109 and the second plate 111 is referred to as a bottom plate 111. The capacitor 112 has a first plate 114 and a second plate 113. Again, for simplicity's sake, the first plate 114 is referred to as a top plate 114 and the second plate 113 is referred to as a bottom plate 113. In the example shown in FIG. 1, the inter-die connection 107 couples to the top plate 109; the inter-die connection 108 couples to the top plate 114; and the bottom plates 111, 113 couple to each other. In FIG. 1, the bottom plates 111, 113 are shown as two separate plates, however, in some examples, the capacitors 110, 112 can be fabricated such that a single conducting plate forms the bottom plates 111, 113. Stated another way, the capacitors 110, 112 may have a single conducting plate acting as the bottom plates 111, 113. The capacitors 110, 112 are a means of preventing the transfer of direct current (dc) and unwanted alternating current (ac) between two parts, such as the transmitter and receiver circuits 105, 116, respectively, while still enabling signal and power transfer between those two parts. The transmitter circuit 105 is configured to operate at a voltage level that is relatively higher than a voltage level of the receiver circuit 116. For example, the transmitter circuit 105 can operate at 1.5 kV, whereas the receiver circuit 116 can operate at 5V. In such a scenario, the relative grounds of the transmitter circuit 105 and the receiver circuit 116 are offset from each other by a high voltage (e.g., 1.5 kV), which results in a voltage difference across the capacitors 110, 112.

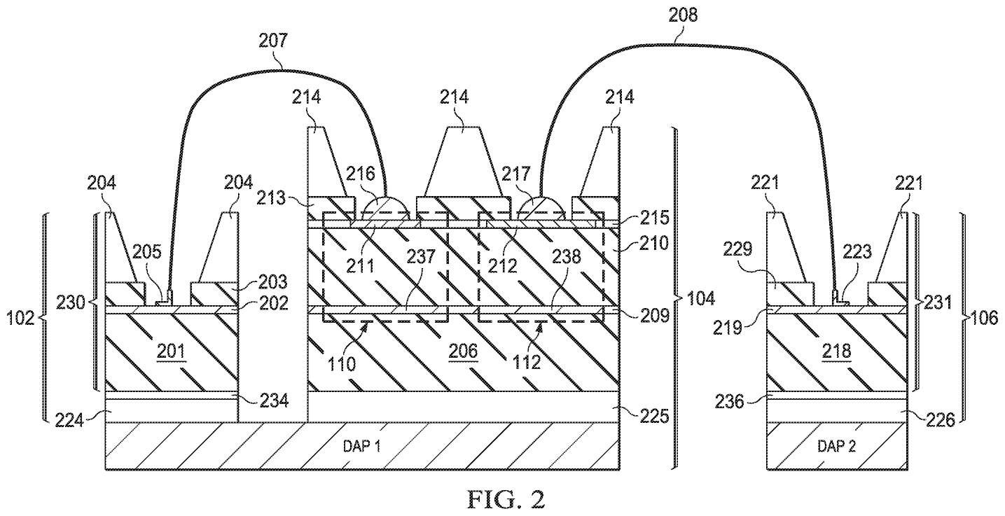

The example of the transmitter and receiver circuits 105, 116, respectively, has been chosen for the sake of illustration. This disclosure applies to the circuit 100 including a collection of microelectronic devices (such as the transmitter circuit 105) forming a first circuit fabricated on a first die (such as the semiconductor die 102) and another collection of microelectronic devices (such as the receiver circuit 116) forming a second circuit fabricated on a second die (such as the semiconductor die 106). In other examples, different digital/analog circuits requiring high voltage isolation may form the circuits positioned on the semiconductor dies 102, 106. The MCM in which the circuit 100 is disposed further includes DAPs, depicted in FIG. 2. In some examples, the semiconductor dies 102, 104, and 106 are disposed on separate DAPs. In such examples, as further described below, the capacitors 110, 112 may be symmetric, meaning that the symmetric capacitors may generate substantially equal capacitance (e.g., capacitance within 10% range of each other). In other examples, the semiconductor dies 102, 104 may be disposed on a single, common DAP; whereas the die 106 may be disposed on a separate, electrically isolated DAP. Positioning the dies 102, 104 on the same DAP, as further described below, may require asymmetric capacitors 110, 112, meaning that the capacitance generated by the capacitors 110, 112 may be unequal. In this disclosure, the semiconductor dies 102, 104, and 106 are sometimes referred to as dies 102, 104, and 106, respectively.

FIG. 2 depicts an illustrative cross-section side view of the circuit 100. FIG. 2 is now described in tandem with FIG. 1. FIG. 2 shows a cross-sectional side view of the die 102 that includes a substrate 224. In one example, a silicon-based substrate may be used as the substrate 224; however, in other examples other suitable semiconductor substrates may be employed. For ease of illustration, only a portion of the die 102 is shown in FIG. 2. From a practical fabricated device standpoint, the die 102 may further comprise a plurality of features (not expressly shown in FIG. 2) such as shallow trench isolation (STI) features or local oxidation of silicon (LOCOS) features. The isolation features define and isolate the various microelectronic elements 234 (or microelectronic devices 234). In some examples, the microelectronic elements 234 form an IC and, therefore, can be referred to as an IC.

For simplicity's sake, the microelectronic elements 234 are depicted by a block. In actual implementation, examples of the various microelectronic elements 234 that may be formed in the substrate 224 include: transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; and other suitable elements. Various processes are performed to form the various microelectronic elements including deposition, etching, implantation, photolithography, annealing, and other suitable processes. The microelectronic elements are interconnected via metallic interconnects to form the semiconductor device (or, in other words, the IC), such as a logic device, sensor device, radio frequency (RF) device, input/output (I/O) device, system-on-chip (SoC) device, combinations thereof, and other suitable types of devices. Therefore, in some examples, the microelectronic elements 234 (or microelectronic devices 234) can be referred to include the IC.

The cross-section of the die 102 further shows a portion 230 disposed on the substrate 224. The portion 230, in some examples, may include pre-metal dielectric layer 201, a metal layer 202. In some examples, a protective overcoat layer 203 and a polyimide layer 204 are supported by the metal layer 202. At least some of the parts comprising the portion 230 provide a pathway between the microelectronic elements 234 and other circuits disposed in the MCM. For example, the portion 230 includes a bonding structure 205 that couples to the metal layer 202. The metal layer 202 electrically couples (through vias and other interconnect metal layers) to the microelectronic elements 234 and to the inter-die connection 207 that connects to the circuitry (or electronic elements, such as capacitors) positioned on other dies. The inter-die connection 207 is similar to the inter-die connection 107 of FIG. 1. The example of the bonding structure 205 shown in FIG. 2 is a stitch bond structure. In other examples, different bonding types may be employed.

Similar to the cross-sectional side view of the die 102, FIG. 2 further shows a cross-sectional side view of the die 106 that includes a semiconductor substrate 226. In one example, a silicon-based substrate may be used as the semiconductor substrate 226; however, in other examples, other suitable semiconductor substrates may be employed. Again, for ease of illustration, only a portion of the die 106 is shown in FIG. 2. From a practical fabricated device standpoint, the die 106, similar to the die 102, may further comprise a plurality of isolation features (not expressly shown in FIG. 2), such as shallow trench isolation (STI) features or local oxidation of silicon (LOCOS) features. The isolation features define and isolate the various microelectronic elements 236. In some examples, the microelectronic elements 236 form an IC and, therefore, can be referred to as an IC.

For simplicity's sake, the microelectronic elements 236 are depicted by a block. In actual implementation, examples of the various microelectronic elements 236 that may be formed in the substrate 226 include: transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; and other suitable elements. Various processes are performed to form the various microelectronic elements including deposition, etching, implantation, photolithography, annealing, and other suitable processes. The microelectronic elements are interconnected via metallic interconnects to form the semiconductor device (or, in other words, the IC) such as a logic device, sensor device, radio frequency (RF) device, input/output (I/O) device, system-on-chip (SoC) device, combinations thereof, and other suitable types of devices. Therefore, in some examples, the microelectronic elements 236 (or microelectronic devices 236) can be referred to include the IC.

The cross-section of the die 106 further shows a portion 231 that is disposed on the substrate 226. The portion 231, in some examples, may include pre-metal dielectric layer 218 and a metal layer 219. In some examples, a protective overcoat layer 229 and a polyimide layer 221 are supported by the metal layer 219. At least some of the parts comprising the portion 231 provide a pathway between the microelectronic elements 236 and other circuits disposed in the MCM. For example, the portion 231 includes a bonding structure 223 that couples to the metal layer 219. The metal layer 219 electrically couples (through vias and other interconnect metal layers) to the microelectronic elements 236 and to the inter-die connection 208 that connects to the circuitry (or electronic elements, such as capacitors) positioned on other dies. The die 106 further includes a bonding structure 223 that couples to the inter-die connection 208 and forms a connection with circuitry (or electronic elements, such as capacitors) positioned on other dies. The inter-die connection 208 is similar to the inter-die connection 108 of FIG. 1. The example of the bonding structure 223 shown in FIG. 2 is a stitch bond structure. In other examples, different bonding types may be employed.

FIG. 2 further depicts the cross-sectional side view of the die 104 that includes the capacitors 110, 112, which are formed on a substrate 225. In one example, a silicon-based substrate may be used as the substrate 225; however, in other examples, other suitable substrates may be employed. Fabricating the capacitors 110, 112 include depositing a pre-metal dielectric layer 206 which, in some examples, can include silicon dioxide. As noted above in FIG. 1, the bottom plates 111, 113 are depicted as two separate plates, however, in the example shown in FIG. 2, the capacitors 110, 112 can be fabricated such that a single conducting plate forms the bottom plates 111, 113 (e.g., by a metal layer 209). Fabricating the capacitors 110, 112 includes depositing the metal layer 209, then patterning and etching layer 209 to form the bottom plates of the capacitors 110, 112. Example metal layer 209 includes aluminum, aluminum alloy, copper, silicide, or implanted silicon. The metal layer 209 is floating, i.e., is not physically connected to ground or any voltage source. The capacitors 110, 112, in the example shown in FIG. 1, employ an inter-level dielectric layer 210. In some examples, the inter-level dielectric layer 210 is thick, e.g., 10 micrometers in thickness. In one example, the inter-level dielectric layer 210 includes silicon dioxide. In other examples, the inter-level dielectric layer 210 can include multiple layers of dielectric material, including silicon dioxide, silicon oxynitride, or silicon nitride.

The capacitors 110, 112 further include metal layers 211, 212 forming the top plates 109, 114, (FIG. 1) respectively. The metal layers or top capacitor plates 211, 212, in some examples, are formed by first depositing a metal layer, and then patterning and etching it. Example metal layers 211, 212 include aluminum, aluminum alloy, copper, or other suitable conducting material. The metal layer 211 and a projection of the metal layer 211 on the metal layer 209 form the capacitor 110. A portion 237 is depicted to be the projection of the metal layer 211 on the metal layer 209. In such an example, the metal layer 211 and the portion 237 form the capacitor 110. In other examples, because of fringing electric fields, the size of the portion 237 can be larger than the projection of the metal layer 211 on the metal layer 209. The metal layer 212 and a projection of the metal layer 212 on the metal layer 209 form the capacitor 112. A portion 238 is depicted to be the projection of the metal layer 212 on the metal layer 209. In such an example, the metal layer 212 and the portion 238 forms the capacitor 112. In other examples, because of fringing electric fields, the size of the portion 238 can be larger than the projection of the metal layer 212 on the metal layer 209.

Fabricating the capacitors 110, 112 further includes depositing a protective overcoat oxide layer 215 between the metal layers 211, 212. In some examples, the protective overcoat oxide layer 215 may be partially disposed (not expressly depicted in FIG. 2) on the metal plates 211, 212. In some examples, the die 104 also includes a protective overcoat layer 213 (e.g., silicon oxynitride, silicon nitride, or other suitable material) and a polyimide layer 214, which are deposited such that the layers 213, 214 cover the metal layers 211, 212 and the protective overcoat oxide layer 215. In some examples, first the protective overcoat layer 213 and the polyimide layer 214 are deposited over the metal layers 211 and 212, such that the deposited layers 213, 214 completely cover the metal layers 211, 212. Following that, a dry film or a photoresist film (not expressly shown) is on the top surface of the polyimide layer 214 through a suitable coating process, which may be followed by curing, descum, and the like, which is further followed by lithography technology and/or etching processes, such as a dry etch and/or a wet etch process, to form openings that exposes at least some portions of the metal layers 211, 212. In some examples, the protective overcoat layer 213 includes silicon oxynitride. The die 104 further includes bonding structures 216, 217 disposed on the metal layers 211, 212, respectively. The bonding structures 216, 217 couple to the inter-die connections 207, 208 and form a series connection with the circuitry positioned on the die 102 and 106, respectively. The example of the bonding structures 216, 217 shows a ball bond structure. In other examples, different bonding types, e.g., stitching bond, may be employed.

FIG. 2 further depicts DAP 1 and DAP 2, which are metal plates employed in MCM to support the dies present in the MCM. In the example shown in FIG. 2, the dies 102 and 104 are disposed on a single DAP, i.e., DAP 1, and the die 106 is disposed on a separate DAP, i.e., DAP 2. As noted above, positioning the dies 102, 104 on the same DAP require capacitors 110, 112 to have asymmetric areas, meaning that the capacitance generated by the capacitors 110, 112 is unequal. The die 102, in some examples, includes high voltage electronic circuitry, e.g., a transmitter circuit operating at high voltage (e.g., >1 kV), and the die on DAP2 can include a component operating at low voltage. In this case, capacitor 112 is connected through top plate 212 to a low voltage component and capacitor 110 is connected through top plate 211 to a high voltage component. Due to capacitive coupling with the high voltage DAP1 substrate, the bottom plates of the capacitors 110, 112 do not float to the mid-point voltage between DAP1 and DAP2. If the capacitors 110, 112 are built with symmetric area, this capacitive coupling generates asymmetric electric fields within the capacitors 110, 112. In such cases, the capacitor, either capacitor 110 or 112, with the highest electric field is at higher risk of early breakdown fails, reducing the isolation capability of the device. Hence, asymmetric area capacitors are needed in the example where dies 102, 104 are positioned on the same DAP, e.g., DAP 1, to counteract the generation of these asymmetric electric fields. FIG. 2 depicts employing asymmetric area capacitors, where employing asymmetric area capacitors substantially balances the electric field across both capacitors 110 and 112 so that these capacitors share the field substantially equally. The area of the metal layer 211 is smaller than the area of the metal layer 212. This difference in the areas results in asymmetric capacitance.

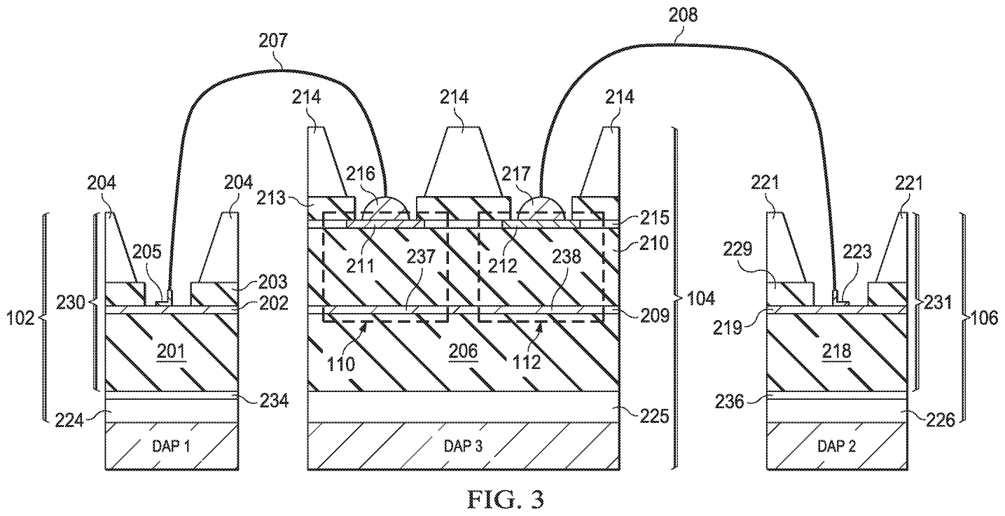

Referring now to FIG. 3, an illustrative cross-section side-view of the circuit 100 is shown. The description of FIG. 2 applies to FIG. 3 except for the position of the dies 102, 104, and 106, which are positioned on separate DAP1, DAP3, DAP2, respectively. Positioning the dies 102, 104, 106 on separate DAPs enables, in some examples, employing symmetric area capacitors 110, 112 on die 104. Using separate DAPs allows the capacitor bottom plate to float to the mid-point voltage between the high voltage DAP1 and low voltage DAP1. In such examples, the electric field on capacitors 110, 112 may then be substantially equal so the area of the metal layer 211 can be substantially equal to the area of the metal layer 212.

Referring now to FIG. 4, an illustrative method 400 including the steps performed at a MCM packaging facility are shown. The method 400 is now described in tandem with FIG. 2. The method 400 begins with placing the die 102 including the microelectronic devices 234 on DAP 1 (step 410; FIG. 2). As noted above, the microelectronic devices 234, in some examples, form an integrated circuit. The method 400 then proceeds to step 420 that includes placing the die 104 that includes a pair of asymmetrical capacitors, i.e., capacitor 110, 112, on the DAP1. The method 400 then proceeds to step 430 that includes placing the die 106 that includes the microelectronic devices 236 (or IC) on the DAP 2. The steps 410, 420, 430 may be performed by a robotic machine. In some examples, die attach or epoxy-based glue is used to firmly place the dies 102, 104 on DAP 1, and 106 on DAP2. The method 400 further includes interconnecting, via the inter-die connection 207, the microelectronic devices 234 and the capacitor 110; and interconnecting, via the inter-die connection 208, the microelectronic devices 236 and the capacitor 112.

In the foregoing discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection via other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means +/−10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

1. A multi-chip module (MCM), comprising:
a first and a second die-attach pad (DAP);
a first die comprising a first set of microelectronic devices;
a second die comprising a first capacitor and a second capacitor; and
a third die comprising a second set of microelectronic devices,
wherein the first and second dies are positioned on the first DAP, and the third die is positioned on the second DAP, wherein the first set of microelectronic devices couples to the first capacitor via a first inter-die connection and the second set of microelectronic devices couples to the second capacitor via a second inter-die connection.

2. The MCM of claim 1, wherein the first capacitor is configured to generate a first capacitance and the second capacitor is configured to generate a second capacitance, wherein the second capacitance is higher than the first capacitance.

3. The MCM of claim 1, wherein the first capacitor comprises a first metal layer and a first portion of a second metal layer, wherein the second capacitor comprises a third metal layer and a second portion of the second metal layer.

4. The MCM of claim 3, wherein an area of the second portion is larger than an area of the first portion.

5. The MCM of claim 3, wherein the second metal layer is floating.

6. The MCM of claim 1, wherein the first set of microelectronic devices are configured to operate at a high voltage.

7. The MCM of claim 1, wherein the first and second capacitors are asymmetric.

8. A multi-chip module (MCM), comprising:
a first die comprising a first integrated circuit (IC) coupled to a first inter-die connection;
a second die comprising a first capacitor and a second capacitor, wherein the first capacitor comprises a first metal layer and a first portion of a second metal layer, wherein the second capacitor comprises a third metal layer and a second portion of the second metal layer; and
a third die comprising a second IC coupled to a second inter-die connection, the first capacitor coupled to the first IC via the first inter-die connection and the second capacitor coupled to the second IC via the second inter-die connection.

9. The MCM of claim 8 further comprising:
a first die-attach pad (DAP);
a second DAP; and
a third DAP,
wherein the first die is positioned on the first DAP, the second die is positioned on the second DAP, and the third die is positioned on the third DAP.

10. The MCM of claim 9, wherein the first capacitor is configured to generate a first capacitance, the second capacitor is configured to generate a second capacitance, and the first and second capacitances are substantially equal.

11. The MCM of claim 8 further comprising:
a first die-attach pad (DAP); and
a second DAP, wherein the first and second dies are positioned on the first DAP, and the third die is positioned on the second DAP.

12. The MCM of claim 11, wherein the first capacitor is configured to generate a first capacitance, the second capacitor is configured to generate a second capacitance, and the second capacitance is larger than the first capacitance.

13. (canceled)

14. The MCM of claim 13, wherein an area of the second metal layer is larger than an area of the first metal layer.

15. The MCM of claim 13, wherein the second metal layer is floating.

16. The MCM of claim 8, wherein the first capacitor comprises a first metal layer and a first portion of a second metal layer, wherein the second capacitor comprises a third metal layer and a second portion of the second metal layer.

17. The MCM of claim 16, wherein the second metal layer is floating.

18. A method of packaging a multi-chip module (MCM), the method comprising:
placing a first die including a first integrated circuit (IC) on a first die-attach pad (DAP);
placing a second die including a pair of asymmetrical capacitors on the first DAP; and
placing a third die including a second IC on a second DAP.

19. The method of claim 18 further comprising:
interconnecting, via a first inter-die connection, the first IC and a first capacitor of the pair of asymmetrical capacitors; and
interconnecting, via a second inter-die connection, the second IC and a second capacitor of the pair of asymmetrical capacitors.

20. The method of claim 19, wherein the first capacitor comprises a first metal layer and a first portion of a second metal layer, wherein the second capacitor comprises a third metal layer and a second portion of the second metal layer, and wherein an area of the second metal layer is larger than an area of the first metal layer.
